(19) United States
(12) Patent Application Publication
(10) Pub. No.: US 2011/0012584 A1
(43) Pub. Date: Jan. 20, 2011

(54) SAFETY DEVICE, PARTICULARLY FOR HOUSEHOLD APPLIANCES

(76) Inventors: Artem Ivanov, Gilching (DE); Reinhard Unterreitmayer, Gauting (DE)

Correspondence Address: KF ROSS PC, 5683 RIVERDALE AVENUE, SUITE 203 BOX 900, BRONX, NY, 10471-0900, US

(21) Appl. No.: 12/446,618

(22) PCT Filed: Mar. 5, 2009
(86) PCT No.: PCT/EP09/01570

§ 371 Date: Apr. 24, 2009

(30) Foreign Application Priority Data
Mar. 5, 2008 (DE) 10 2008 012 795.7
Jul. 4, 2008 (DE) 10 2008 031 743.8
Jul. 4, 2008 (DE) 10 2008 031 774.8

(51) Int. Cl. G01R 31/02

(52) U.S. Cl. 324/72

(57) ABSTRACT

The invention relates to a safety system for detecting the presence of living beings inside a lockable, or alternatively dangerous housing area, particularly the washing housing area of a washing machine or of a clothes dryer, of a stove, of a microwave oven, as well as particularly also in closets and chests. According to a first aspect of the present invention the aim at the beginning is solved by means of a safety device for detecting the presence of living beings inside a dangerous housing area with a first electrode device which, as such, is facing the housing area and is a component of a LC network, and a second electrode device which is also facing the housing area and is a component of a LC network, and an evaluation circuit for detecting the dynamics of electric field interactions with at least one of the two electrode devices in which the detected dynamics is compared with the comparison values provided for the current working condition of the housing area, so that, if the detected dynamics differs from the provided comparison values, a safety function is activated.

### FIELD OF THE INVENTION

The invention relates to a safety system for detecting the presence of living beings inside a lockable, or alternatively dangerous housing area, particularly the washing housing area of a washing machine or of a clothes dryer, a stove, a microwave oven, as well as also particularly in closets and chests.

### OBJECT OF THE INVENTION

The object of the invention is to provide solutions by which the presence of living beings in a the housing area is detected and dangers to the living beings, particularly small children and pets, can be reliably avoided.

### SOLUTION ACCORDING TO THE INVENTION

According to a first aspect of the present invention the object at the beginning is solved by means of a safety device for detecting the presence of living beings inside a dangerous housing area with:
a first electrode device which, as such, is facing the housing area and is a component of a LC network, and
a second electrode device which is also facing the housing area and is a component of a LC network, and
an evaluation circuit for detecting the dynamics of electric field interactions with at least one of the two electrode devices, wherein the detected dynamics is compared with the comparison values provided for the current working condition of the housing area, so that, if the detected dynamics differs from the provided comparison values, a safety function is activated.

The safety function can consist in stopping a dangerous operation, particularly in an appliance disconnection. Moreover, it is possible to form the appliance in such a way that the safety function consists in an alarm issue. This alarm issue can particularly occur in acoustic, and/or visual ways. Moreover, it is possible to form the appliance in such a way that the safety function consists in unlocking a door device.

Preferably the safety device is formed in such a way that the safety function requires an user's activation to continue the operation. Such an user's activation for example can consist in a required opening of a door and preferably also in reaching into the housing space. This reaching into is also accomplished in advantageous way on the basis of electric field interaction effects, particularly directly through the receiving electrodes.

Preferably, first of all a starting operation with reduced dynamics is promptly started. By this it is possible first of all to shake awake a possibly asleep cat and to detect it reliably through its own movement. According to that starting operation the presence of dynamic characteristics is preferably checked.

The first electrode device is preferably operated as a transmitting electrode, for the coupling of an electric field in a section of the housing area to be observed.

The second electrode device is preferably constructed as a receiving electrode device. Both electrode devices are preferably operated in such a way that differences of the electric fields adjacent to them are detected.

Particularly in the case of a washing machine, or of a clothes dryer, the transmitting field is preferably generated by electrode devices which are connected to a housing drum. The receiving electrodes are preferably connected to a detection circuit which as such generates signals which are caused by differences between the fields adjacent to the receiving electrodes, or by bridging effects between the two receiving electrodes. A technical signal feedback of the events detected through the detection circuit to a server circuit can occur by means of the transmitting electrode system. Here the detection circuit is preferably supplied with energy by means of the electric field adjacent to the receiving electrodes. The signal feedback to the transmitting electrode system can occur particularly through impedance modulation in the area of the receiving electrodes.

According to a further aspect the invention also deals with a contact and approach detection by means of capacitive sensors.

In this respect, the invention relates to a sensor device for detecting an approach of an object in an observation area monitored by the sensor device.

The object of the invention is to show solutions by which the presence of objects, particularly of living beings, in the observation area can be reliably sensed or detected.

Therefore, according to the invention, a sensor device is provided for detecting an approach of an object in an observation area monitored by the sensor device in which the sensor device comprises a server circuit with:
a LC oscillatory circuit with a signal-generating circuit, preferably a high-quality LC oscillatory circuit, for generating an electric field,
an electrode device coupled with the LC oscillatory circuit in which the capacitance of the electrode device is a component of the oscillatory circuit capacitance and in which the electric field generated by the LC oscillatory circuit can be radiated on the electrode device in the observation area, and
an evaluation device, wherein the approach of an object, particularly of a living being, in the observation area of the electrode device causes a change in the capacitive environment of the electrode device, which is detectable by the evaluation device.

Preferably the signal-generating circuit is constructed as an oscillator and the LC oscillatory circuit as a LC series resonant circuit, where the electrode device is connected in parallel to the LC oscillatory circuit. The oscillator and the LC series resonant circuit can thus form a free-running LC oscillator.

The LC oscillatory circuit can also be constructed as a LC parallel resonant circuit in which the electrode device is connected in series to the LC oscillatory circuit.

Further embodiments of the LC oscillatory circuit and of the arrangement of the electrode device for the LC oscillatory circuit are possible.

The high-quality LC series resonant circuit leads to an effective increase in the voltage amplitude in the electrode device, as well as to an increased sensitivity to load modulation in this electrode device. The high quality of the LC series resonant circuit at the same time implies that it generates a very stable frequency, which depends on the inductance and capacitance values in the oscillatory circuit.

The sensor device is preferably operated in such a way that the change in the capacitive environment of the electrode device causes a change in the frequency of the (free-running) LC oscillator, where the frequency change is detectable by the evaluation device. The approach of an object in the observation area of the electrode device thus leads to a change in the capacitive environment of this electrode device, which in turn leads to a change in the oscillator frequency. Therefore, through the approach of an object the oscillator signal is frequency modulated, where this frequency modulation is detectable by the evaluation device.

The signal-generating circuit can also be constructed as a generator. Preferably the generator is then operated in resonance to the LC oscillatory circuit, which has the advantage that even particularly small capacitance changes, for example capacitance changes of 1 pF or smaller, can be detected in the electrode device. In this case the capacitance change in the electrode device is detected by the evaluation device on the basis of the signal phase shift.

The server circuit can advantageously be operated also in conjunction with at least one client circuit. To this end, the sensor device also comprises at least one client circuit, with:

a second electrode device, comprising at least one first electrode and at least one second electrode, and

a modulation device coupled with the second electrode device in which the electric field radiated by the electrode device of the server circuit can be coupled with the first electrode of the second electrode device in which the coupled electric field can be modulated through the modulation device, wherein the modulated signal can be sent back through the electrode device of the server circuit, preferably by means of load modulation, to the server circuit and in which the signal sent back can be detected and evaluated by the evaluation device.

In this way, in a particularly advantageous embodiment of the invention a sensor device is provided, which allows to detect the approach of an object to the electrode device of the server circuit in case of simultaneous modulation of the signal radiated by the electrode device of the server circuit through the client circuit, where through the evaluation device, besides the frequency modulation, the modulation through the client circuit is detectable as well.

The approach of an object to the second electrode of the second electrode device can cause a modulation of the coupled electric field through the modulation device. In this way the evaluation device, besides the approach of an object to the electrode device of the server circuit, can also detect the approach of an object to the second electrode of the client circuit. The evaluation device can also detect the presence of an object on the second electrode of the client circuit, for instance the presence of a lint filter in a clothes dryer.

The first electrode can also be formed through the electrode device of the server circuit, so that a capacitive coupling of the electric field of the first electrode of the second electrode device is not necessary. In this embodiment, too, an approach of an object to the second electrode of the second electrode device causes a modulation of the electric field generated by the electrode device of the server circuit.

The coupling of the electric field to the first electrode of the client circuit can take place through bridging, where the bridging causes a modulation of the coupled electric field through the modulation device. Because of the bridging effect, the client circuit can be arranged with respect to the server circuit in such a way that an approach of an object, particularly of a living being, in the area between the electrode device of the server circuit and the first electrode of the client circuit is detectable. In such an arrangement of the client circuit with respect to the server circuit the second electrode of the client circuit is preferably coupled to earth.

With the coupled electric field the client circuit can be also supplied with energy, so that a client circuit without internal power supply can be made, which is particularly advantageous especially in terms of size and of field of application.

The modulation device is preferably constructed in such a way that the coupled electric field is amplitude-modulated, where the change in the amplitude is detectable by the evaluation device.

Preferably an approach of an object in the observation area of the electrode device of the server circuit is detectable, whereby an approach of the object to the second electrode of the second electrode device is also detectable.

More preferably, an approach of an object in the observation area of the electrode device of the server circuit is detectable just before the approach of the object to the second electrode of the second electrode device. In this way, an approach of an object to the sensor device can be detected even before the detection of an approach of the object to the client circuit.

Moreover, the invention also deals with a sensor device for determining the amount and/or the degree of humidity of the washing in a clothes dryer.

In this context, the invention relates to a sensor device for a clothes dryer with a drum which, with the aid of an electric field radiated in the drum of the clothes dryer, determines the amount and/or the degree of humidity of the washing situated in the drum.

The optimization of the drying process in a clothes dryer with respect to the necessary time and energy consumption requires knowledge of the amount of wet washing or of the water contained in the washing.

In the prior art, it is known to determine the degree of humidity of wet washing in a clothes dryer with the aid of special water sensors in conjunction with a software analysis. In this respect, it is disadvantageous that the water sensors must be arranged inside the drum or that the water sensors are located in direct contact with the wet washing situated in the drum.

In order to ascertain the amount of wet washing in a drum, in the prior art it is known, for example, to determine the weight of the washing placed in the washing drum. From the weight it is also possible to infer the amount of water contained in the washing. In particular, this method has the disadvantage that the own weight of the washing, for example of a heavy jacket, is not considered. In order to avoid this disadvantage, in the prior art it is known to lengthen the drying time, in order to certainly guarantee the drying of the washing. This leads to the fact that in certain conditions the drying process lasts longer than necessary which, at the same time, also means a higher energy consumption.

Therefore, the object of the present invention is to provide a sensor device for a clothes dryer for determining the amount and/or the degree of humidity of the washing placed in the drum of the dryer and to avoid the disadvantages of the prior art at least partially.

According to the invention it is thus provided a sensor device for a clothes dryer, where the sensor device comprises:

a circuit for generating an electric field, which can be radiated on at least one electrode coupled to the circuit, and

a evaluation circuit for detecting electric field interactions between the at least one electrode and a counter electrode in which the electrode is arranged in the area of the drum and is insulated from the drum and in which the detected electric field interactions are characteristic of the amount and/or the degree of humidity of the washing situated in the drum.

The special advantage of the sensor device according to the invention is that, by using electric field interactions or capacitance changes between an electrode and a counter electrode, the degree of humidity of the washing which is placed in the drum of a clothes dryer can be determined particularly well. Additionally, with the sensor device according to the invention, the amount of washing can be ascertained as well. Another advantage is that the energy efficiency of a clothes dryer can be improved or that energy consumption can be considerably reduced.

Moreover, the electric field interactions detected by the evaluation circuit are also characteristic of the drum rotation. Thereby, it is possible to easily determine if the drum is moving or not.

Preferably, the circuit has a free-running LC oscillator for generating the electric field or the electrode voltage on the electrode coupled with the circuit.

Thereby, the LC oscillator can consist of a serial LC oscillatory circuit in which the electrode is part of the capacitance of the oscillatory circuit. In this way, the necessary increase in the electrode voltage in the electrode is achieved as well.

The circuit can also be used as a server circuit, whereby the electrode serves as a server electrode. In this way, other events in the washing drum can be detected as well.

The sensor device is constructed in such a way that the rotation of the drum causes a change in the capacitive environment of the electrode, which causes a frequency modulation of the oscillator frequency of the circuit. From the frequency-modulated oscillator frequency the rotation of the drum and/or the degree of humidity of the washing and/or the amount of washing in the drum can be deduced or determined.

In a preferred embodiment the electrode is arranged asymmetrically with respect to the vertical axis in the drum. In this way it is also possible to determine the drum rotation direction, provided that (wet) washing is situated in the drum.

However, the rotation direction can also be known, so that with the aid of the rotation direction from the frequency-modulated signals the amount of washing or the degree of humidity of the washing can be determined.

Two similar frequency-modulated signals with respect to both drum rotation directions are characteristic of a fully loaded drum. From this it can be deduced that the capacitive environment of the electrode during a drum rotation changes only very little or does not change at all, when the drum is fully loaded, as in the drum there is not enough space for the washing to move inside the drum.

The electrode can also be constructed in such a way that the drum rotation direction can be determined also without (wet) washing in the drum. For example the electrode itself can be asymmetrically shaped with respect to its own axis or the electrode can develop asymmetrically with respect to the drum rotation direction (cf. FIG. 2).

The counter electrode too can have an asymmetrical shape. The shape of the counter electrode can also develop asymmetrically with respect to the drum rotation direction.

The at least one counter electrode can be arranged on at least one of the drum lifters, whereby the counter electrode is preferably arranged on the electrode-facing side on the lifter.

In a particular embodiment of the invention the at least one counter electrode can consist of at least one drum lifter. In this embodiment it is particularly advantageous that inside the drum no additional means or instruments must be provided for the operation of the sensor device according to the invention. This allows a particularly inexpensive and low-expenditure installation of the sensor device according to the invention in a commercial clothes dryer.

In a further embodiment the counter electrode is made up of the washing itself.

In a further aspect the invention deals with a method for determining the rotation of a clothes dryer drum and/or the amount and/or the degree of humidity of the washing in a washing drum, where the method comprises at least one of the following steps:

1) Rotating the drum clockwise;
1.1) Determining the relative changes in the signal by using the sensor device according to the invention; and/or
1.2) Determining the absolute changes in the signal with respect to a predetermined reference signal by using the sensor device according to the invention;

2) Rotating the drum counterclockwise;
2.1) Determining the relative changes in the signal by using the sensor device according to the invention; and/or
2.2) Determining the absolute changes in the signal with respect to a predetermined reference signal by using the sensor device according to the invention;
2.3) Comparing the results obtained in steps 2.1) and/or 2.2) with the results obtained in steps 1.1) and/or 1.2);

3) Determining the drum rotation and/or the amount of washing and/or the degree of humidity of the washing.

Moreover, the method according to the invention can present a step for defining a reference signal, which is characteristic of a drum motion in the empty state. This reference signal can be stored in the sensor device, preferably in the server circuit, more preferably in the evaluation circuit. For this purpose, the sensor device, the server circuit or the evaluation circuit can be provided with an (additional) nonvolatile storage. A reference signal can be defined and stored both for a clockwise rotation and for an counterclockwise rotation. The reference signals with respect to both rotation directions in case of an empty drum differ, particularly, if the electrode develops asymmetrically with respect to its own axis.

### BRIEF DESCRIPTION OF THE FIGURES

Further details and characteristics of the invention will appear from the following description in conjunction with the drawings in which:

FIG. 1 is a schematic representation which illustrates the workings of a safety device according to the invention in a clothes dryer;

FIG. 2 is a schematic circuit diagram which illustrates the workings of a circuit according to the invention constructed including the receiving electrodes particularly for a clothes dryer or a washing machine

FIG. 3 is a schematic representation which illustrates the arrangement of the electrodes in a clothes dryer or a washing machine;

FIG. 4 is another schematic representation which illustrates the arrangement of the electrodes in a clothes dryer or a washing machine;

FIG. 5 is yet another schematic representation which illustrates the arrangement of the electrodes in a clothes dryer or a washing machine;

FIG. 6 is a schematic representation which illustrates a field line progression;

FIG. 7 is another schematic representation which illustrates a field line progression;

FIG. 8 is another schematic representation which illustrates the arrangement of the electrodes in a clothes dryer or a washing machine;

FIG. 9 is a basic set-up of a circuit diagram of a server circuit of the sensor device according to the invention which illustrates the workings of the server circuit,

FIG. 10 is a basic set-up of a circuit diagram of a sensor device according to the invention, which comprises a server circuit and a client circuit in which a first variant of approach of an object to the sensor device is shown; and

FIG. 11 is a basic set-up of a circuit diagram of a sensor device according to the invention with a server circuit and a client circuit in which another variant of an approach of an object to the sensor device is shown.

FIG. 12 is the embodiment of a sensor device and its arrangement in a washing drum of a dryer according to the present invention; and

FIG. 13 is a possible embodiment of an electrode or counter electrode.

### DETAILED DESCRIPTION OF THE INVENTION

The safety device according to the invention is particularly suitable for the detection of a child or animal in the drum of a washing machine or of a clothes dryer. Through the safety device according to the invention a dryer (a washing machine) can be prevented from carrying out its function to a dangerous extent, when a child is situated in the drum. The detection takes place on the basis of capacitive, e.g. electric field interaction effects. The detection according to the invention in a drum occurs by considering the latter as a cylindrical conductive hollow space with an open side. The walls are preferably on the earth potential (GND). The detection takes place from the area on the door side.

The capacitive sensors according to the invention detect a change in the electric field through the object as compared with the undisturbed state.

In the considered system, the energy density of an electrostatic field, which has its source in the area of the opening, considerably decreases with depth.

In a such system the measuring device (sensing electrode) too must be in the area of the opening, e.g. near the field source.

A (very small) change in the measuring signal on a high level of the permanently present signal can be detected.

In addition, smaller objects lying near the opening can create greater signal changes than bigger objects at the bottom of the hollow space.

It is also possible that closer objects electrically shield the further away lying objects at least to a great extent. Preferably the drum is connected as a “transmitting electrode”.

The receiving electrodes are preferably designed and arranged in such a way that their signals can be used for a reciprocal “compensation”.

Electronics is constructed accordingly.

The detection principle preferably consists in registering the movement of the living being to be detected and in not “detecting” static and common-mode signals.

A particularly advantageous simplification, which derives from the presentation of the problem—relative results are sufficient, no absolute precision is required.

The measuring system can be constructed following the acquisition technique described in DE 10 2007 020 873.3. The complete system comprises as few spots, which have a connection to GND, as possible. On the contrary, the measuring system is supplied with an operating voltage, which itself oscillates relative to GND with the operating frequency and operating amplitude. Seen from the point of view of the internal earth of the system (from the “viewpoint of the electrodes”), the whole environment oscillates with the operating frequency and operating amplitude.

In order that all the (earthed) environment objects become “transmitters”, the field to be measured establishes between the objects and the electrode system.

In this case the ground “does not absorb the field”, but rather “supplies” the field, and the range becomes maximum. Preferably, the electrodes are symmetrically constructed and supply equal signals in a symmetric (or symmetrized) environment. As these signals are processed in 2 parts (composite signal+differential signal), the detection of small changes in the ample quasiconstant signal is possible.

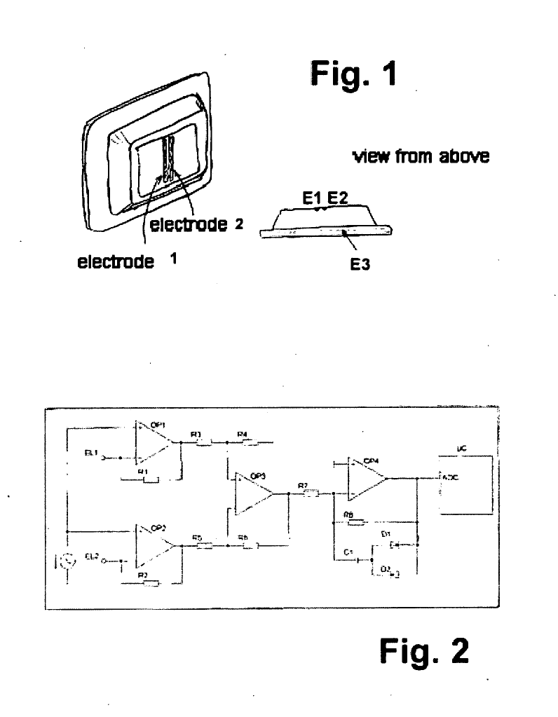

The electrode system preferably consists of two electrodes, that are preferably commensurate, stripe-shaped constructed and are arranged vertically in the middle of the drum door (symmetric) parallel to each other (FIG. 1). The signals of the electrodes are differentially analyzed, so that only the asymmetry in them is determined. This means that in case of empty drum and closed door the system output signal will be 0 (at least approximately). Considering the geometry, the system is sensitive to changes in the X-axis (horizontal direction) and has no sensitivity in the Y-axis (vertical direction).

The vertical direction of the electrodes is selected to minimize the influence of the wet washing (which roughly lies horizontally) on the symmetry. For the same reason the electrodes should be close to each other. Electrode measures (first proposal): width—10 mm, length—200 mm (full height of the inner part of the door), distance from each other—10 mm.

Another advantage of the use of two substantially equal electrodes arranged close to each other with differential evaluation is the effective attenuation of external disturbances (e.g. mains hum).

The exemplary basic circuit is illustrated in FIG. 2. Operational amplifiers OP1, OP2, OP3 constitute an instrumentation amplifier with transimpedance inputs. The electrodes EL1 and EL2 are located on virtual earth, that oscillates with operating frequency (in the range of about 10-100 kHz) as to GND/earth. The extracted differential signal is received at the OP3 output. This can be further amplified, i.a. with a logarithmic characteristic, as illustrated as an example in FIG. 2, in order to emphasize the smaller signals of further away objects relative to ample signals of the objects nearby. This signal arrives in a μC (ADC) where it is evaluated e.g. according to a synchronous detection (as in a clover).

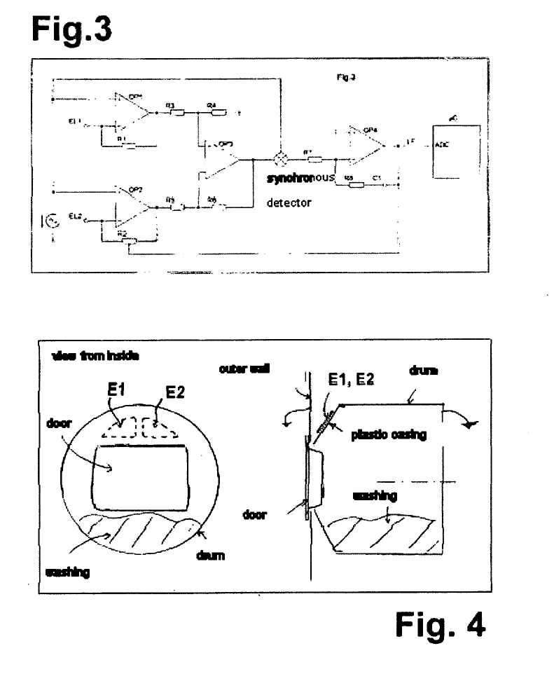

Another possibility of analysis (schematic diagram in FIG. 3) is based on the approach, that the difference of the signals is analogously stabilized by both electrodes. The low-frequency controlled variable is here used to draw conclusions on possible movements in the drum.

The fact that an absolute initial value is not necessary makes it possible to construct the (nonlinear) amplifiers easily from the technical viewpoint of the system—which through the drifts caused by temperature changes have much larger time constants than the wanted movement in the drum.

The measuring process to be used would look as follows: after pushing the START button a short side sway (or rotation) of the drum is carried out. After this motion has calmed, a possible motion of electric field relevant objects in the drum is examined for a predetermined period of time. For good measure or in case of unclear results the procedure can be repeated.

Since the sensitivity of the system to the small signals strongly depends on the symmetry condition in the electrodes, when necessary the following “symmetrization” procedure could be performed: after the first side sway of the drum the output signal is controlled and if it significantly differs from 0 (too strong asymmetry) the drum is slowly driven to a continuous control of the output signal. The object is to reach the symmetry of the measuring system—to bring the output signal to 0. In this way the field changes at a greater distance from the electrodes can be better measured.

Discrimination with respect to the outside: it is advantageous to distinguish the movements in the drum from the movement outside the machine, or not to react to the outside movement or not to “see” it. This can occur on the one hand through the physical shielding of the environment from inside the drum—e.g. through an earthed electrode at the drum opening (E3 in FIG. 1).

Another variant is the logic discrimination, through the limitation of the spatial measuring range of capacitive sensor systems which will be described in more detail hereinafter.

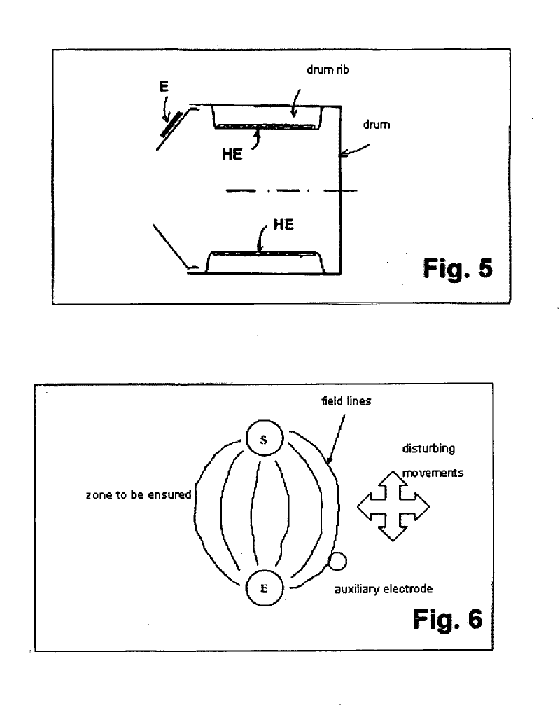

A particularly advantageous electrode arrangement is illustrated in FIG. 4. In this variant the sensing electrodes E1 and E2 are situated behind the plastic drum cover (drum casing) over the door opening. In this position the electrodes are shielded from external influences by the outer wall of the machine. The electrodes are situated near the drum inside and yet sufficiently far from the wet washing—the symmetry in the measuring system is substantially undisturbed. The whole measuring assembly is situated inside the “main case”—no cables must be laid in the door.

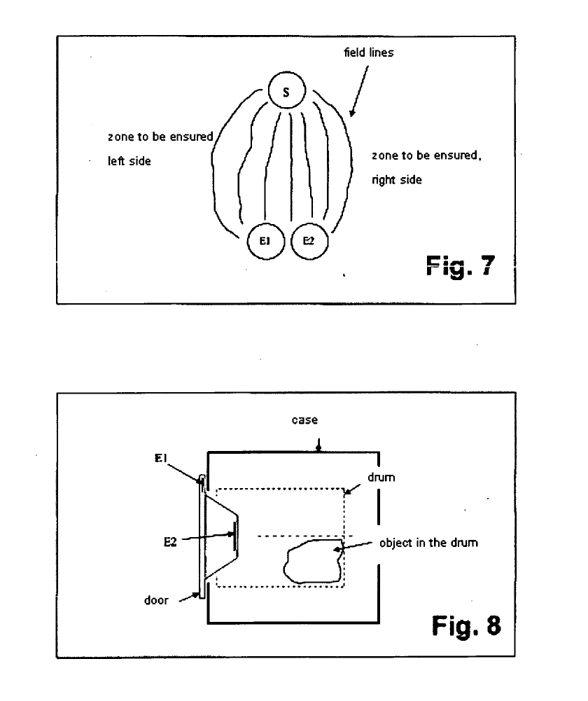

FIG. 5 shows a possible positioning of the auxiliary electrodes (HE). These auxiliary electrodes are used for enhancing the field of the main electrode (e) in the back part of the drum. They can be realized as a metallization inside the drum ribs (e.g. as conductive varnish, conductive plastic, metal strips). Their operating principle consists in that they—as equipotentials of the electric field—bring the higher field at the drum opening inside the drum. The bigger their surfaces are and the further from the drum wall they are located, the better will be their function. Such auxiliary electrodes can be useful with any main electrons.

Furthermore, the safety system according to the invention can be realized by accomplishing an approach and change of the capacitive environment of the electrode with the aid of a ZPS-Server system. A ZPS-Server system is a system in which a transmitting electrode device is controlled through a main circuit in such a way that it radiates a modulated electric field. This field is used for generating detection events by means of a receiving electrode system. The detection events can be sent back by means of a technical signal to the ZPS-Server system, so that in the area of the electrode receiving system a data technical modulation of the input impedance occurs. This impedance change can be ascertained in the area of the ZPS-Server.

Particularly in a washing machine or a clothes dryer, or even a microwave, a receiving electrode device can be applied at the door, where the receiving electrode device is connected to a detecting circuit which is directly supplied with energy through the receiving electrodes.

The detection of approaches to the receiving electrodes can take place particularly through changes in the dielectric characteristics of the environment of the receiving electrodes. Moreover, significant amplitude variations, phase variations or frequency changes are detected inside the LC network constructed including the receiving electrodes.

Preferably the ZPS-Server with a free-running LC oscillator has at its disposal a high-quality oscillator. The main object thereof is an effective enhancement of the voltage amplitude in the electrode and also of the sensitivity to load modulation. This high quality at the same time implies that the oscillator generates a very stable frequency, which depends on the inductance and capacitance values in the oscillatory circuit.

Since the capacitance of the server electrode parallels the capacitance of the oscillatory circuit, the oscillator frequency varies with the change in the capacitive environment of the electrode. The change in the electrode capacitance is usually in the range 1-100 pF. Such a change leads to a relevant change in the oscillator frequency: about 0.1-10 kHz in currently set values.

Also a capacitance change of just 1 pF can be established within 10 ms directly in the microcontroller of the server. (For this a server with synchronization on oscillator frequency must be used, e.g. LC Server V7.3).

In case of installation of the ZPS-Client in the operating panel of an appliance: the approach of the hand to the panel is detected even before the operation of a ZPS-Client. In case of use of a ZPS sensor network in a dryer: if a part of the server electrode is in (weak) capacitive coupling with the inside of the drum, “Child Detection” and “Drum Rotation” (in case of use of conductive lifters) can take place on the basis of the measurement of the frequency change of the oscillator of the ZPS-Server. The electrode can be situated e.g. over the door in the plastic cover of the drum.

In the car: in case of an electrode of the ZPS-Server incorporated in the seat it is possible to distinguish between a real operation of the ZPS and an increased level in the wanted ZPS frequencies due to people sitting on the seat—in the second case there is a large frequency change.

For example, in case of a measuring time of 10 ms a person can be detected at a distance of about 50 cm detected, a hand at the distance of about 10 cm (in 15 cm long wire electrode). The increase in the measuring time and in the electrode surface improves sensitivity.

Moreover, the invention also deals with technical solutions for limiting the spatial measuring range of capacitive sensor systems.

The capacitive detecting sensors according to the invention are based on the measurement of the change in the electric field through a conductive object for displacement currents. Preferably, the measuring system according to the invention substantially does without field forming, thus a large field expansion is achieved. Moreover, the field amplitude is measured at additional spots, in order to “logically” limit the spatial measuring range with the obtained data during the signal analysis.

### Examples

FIG. 6. Access to a production machine is to be ensured. The area is situated between the transmitters (S) and the receivers (E), which work in absorption mode. The machine is situated on the right of transmitters and receivers, which has movable (conductive) parts, which can come near the S-E line. In order to distinguish these parts from a person (coming from left side), an auxiliary electrode can be used (auxiliary receiver).

Thanks to the system geometry the auxiliary electrode reacts much more sensitively to the machine than to the person. Thus, from the logic correlation of the signals of both receivers, it can be decided if the signal change was caused by a person or by the motion of the machine. The effective spatial measuring range of the system is reduced accordingly.

FIG. 7. A more general embodiment of an absorption-mode measuring system with discrimination of the detection direction.

FIG. 8. Movement detection in a washing machine/dryer drum (with respect to detection of children or animals). As an example the Loading-Mode method is displayed.

Here an object movement in the drum can be distinguished from an object movement outside the machine. Therefore, besides the real sensing electrode (E1), which detects the field change in its environment, the auxiliary electrode (E2) is used as well. This auxiliary electrode is shielded by the case of the machine from the drum inside. Therefore, from the logic correlation “Motion detected on E1” and “Motion detected on E2” it inevitably follows that this movement occurred outside.

The spatial measuring range is reduced in case of need. Some applications are possible only in this way. No particular arrangements for field forming must be met, in this way the range is maximized.

The solution of the function “Children-Detection” is obtained with the aid of a load modulation in an electric alternating field. The modulation of the electric field, which is generated through an electrode in the access area of the drum, takes place through electronic switches. The electronic switches are situated in various locations in the drum and are supplied with the necessary operational energy through the electric field. Each of these switches has its own modulation frequency, its modulation deviation represented in the total frequency image depends on the presence of a child or even on a change in the position of the latter.

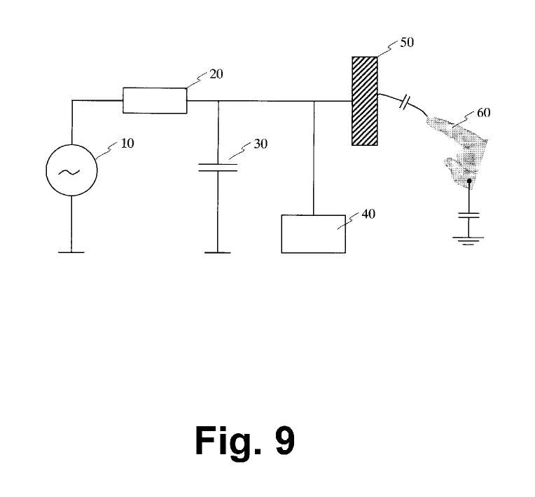

FIG. 9 shows a basic circuit of a server circuit of the sensor device according to the invention. The server circuit substantially consists of a generator 10 and of a LC series resonant circuit formed by inductance 20 and capacitance 30. In this respect, the generator 10, the inductance 20 and the capacitance 30 can form a free-running LC oscillator. Parallel to the LC series resonant circuit lies a server electrode 50, as well as an evaluation device 40.

First of all the generator 10 of the server circuit generates an alternating voltage, which is fed to the LC series resonant circuit 20, 30, thus increasing the signal level, in order to subsequently generate an electric field with a sufficiently wide range. The generated electric field is emitted on an electrode 50, where the electric field emitted by the electrode 50 defines the observation area to be observed by the server circuit.

The LC oscillatory circuit is preferably a high-quality oscillatory circuit. The main object thereof is an effective increase in the voltage amplitude in the electrode 50 as well as an increase in the load modulation sensitivity on this electrode.

As the capacitance of the server electrode 50 parallels the oscillatory circuit capacitance 30, the oscillator frequency varies with the change in the capacitive environment of the server electrode 50. The change in the electrode capacitance of the electrode 50 is usually in the range 1-100 pF. Such a change leads to a relevant change in the oscillator frequency, for example to a change between 0.1 and 10 kHz.

The evaluation device is constructed in such a way that it can detect the change in the oscillator frequency and thus it can recognize an approach of an object 60, particularly of a living being, to the electrode 50. The approach of a living being 60 is schematically shown with a hand in FIG. 1, where through the approach to the server electrode 50 the field radiated by this is partially absorbed by the object 60, which leads to a change in the capacitive environment of the server electrode 50.

For example, the evaluation device 40 can be constructed in such a way that the frequency change of the signal generated by the LC oscillator can be compared with a reference signal, which for example is generated by a quartz stabilized oscillator. The comparison of the frequency of the oscillator signal with the frequency of the reference signal can take place with various means known in the prior art. However, the quartz stabilized oscillator can also be used as a cycle for a counter in which the counter measures the frequency of the oscillator signal within a predetermined number of cycles. With measurements following each other over time within several time intervals of equal cycle length it is possible to determine whether the frequency of the oscillator signal changes or not.

On the basis of the structure of the server circuit according to the invention with a generator and LC series resonant circuit temperature induced frequency changes in the server circuit can be efficiently detected, as the order of magnitude of a temperature induced change in the oscillator frequency on the basis of the large time constant of a temperature change is much smaller than a change, which is determined by an approach of an object to the server electrode 50.

The inductance 20 and the capacitance 30 can also be stimulated by a generator 10 with fixed frequency, whereby the detection of an approach occurs by means of the phase shift of the signal. It is particularly advantageous if the generator 10 is operated in resonance to the LC oscillatory circuit.

The server circuit according to the invention also enables particularly small capacitance changes, for example of 1 pF or smaller, within a very short time, for example within 10 ms, to be detected directly by the server circuit or by the evaluation device. Moreover, longer measuring intervals also allow the detection of very small frequency changes caused by the capacitance change in the electrode.

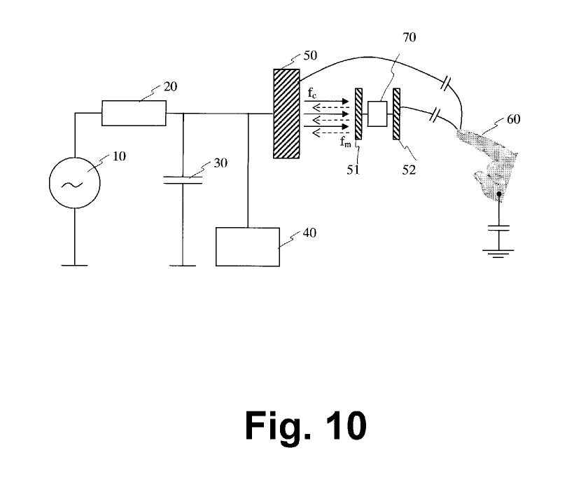

FIG. 10 shows another advantageous embodiment of a sensor device according to the invention. The server circuit is constructed as shown in FIG. 1. Furthermore, the sensor device presents a client circuit. The client circuit substantially consists of an electrode device with two electrodes 51 and 52 as well as a modulation device 70 in which the electrodes 51, 52 are coupled with the modulation device 70 from time to time.

The electric field f_{c} generated by the server circuit and emitted on the server electrode 50 is coupled with the first electrode 51 of the client circuit. At the same time, this coupled field can also be used to supply the client circuit with energy. The coupled electric field f_{c} is modulated by the modulation device 70. The modulated signal fₘ is sent back through the server electrode 50, preferably by means of load modulation, to the server circuit, where it is fed to the evaluation device 40.

The modulation of the signal carried out by the modulation device 70 of the client circuit is evaluated by the evaluation device 40. By doing this, the electric field is amplitude-modulated by the client circuit or by the modulation device 70.

Should an object approach the second electrode 52, as shown in FIG. 2, this would cause a change in the level of the modulation device, which leads to a changed amplitude of the modulated electric field. This changed amplitude is detected and evaluated by the evaluation device 40.

At the same time, an approach of an object to the client circuit can imply that also a part of the electric field radiated by the server electrode 50 is absorbed by the object. The absorption of the electric field in turn implies, as already described above in FIG. 1, that the frequency of the signal radiated by the server electrode 50 changes. In this case both a frequency modulated and amplitude modulated signal is fed to the evaluation device 40. In this way, both an approach of an object to the server electrode 50 and to the electrode 52 of the client circuit can be detected.

In a corresponding arrangement of the client circuit with respect to the server electrode 50 an approach of an object to the server electrode 50 can be detected, even before the detection of the approach of the object to the client circuit.

For instance, this can be used advantageously in an operating panel of an appliance, for example for a washing machine. Should the operating panel of an appliance present several client circuits in which every client circuit can be assigned a specific action, and in which a part of the operating panel is formed as a server electrode 50, the approach of a hand to the operating panel can be detected even before the operation or before the approach of the hand to the client circuit. The early recognition of the approach of an object to the server circuit or server electrode 50 has the particular advantage that for example necessary initialization measures can already be carried out, even before the hand reaches the electrode 52 of the client circuit.

Another example of use of the sensor device according to the invention is the use in a clothes dryer. When a part of the server electrode 50 is in (weak) capacitive coupling with the drum inside, a “Child in the Drum” detection or a “Drum Rotation” detection (with the use of conductive lifters) can occur by means of the measurement of the frequency change of the oscillator 10 of the server circuit. However, at the same time a part of the server electrode 50 can also be used to operate a client circuit as shown in FIG. 2.

Another example of use of the sensor device according to the invention is for instance the installation of the server electrode 50 and of one or more client circuits in a car seat for the purpose of seat occupation recognition. Here the advantage of the embodiment of the sensor device according to the invention becomes particularly clear. It is possible to distinguish between a real operation of the client circuit (which leads to an amplitude modulation of the signal) and an increased level of the signal, which is caused by a person sitting on the seat. In the second case, besides the signal level change, there is also a particularly large frequency change.

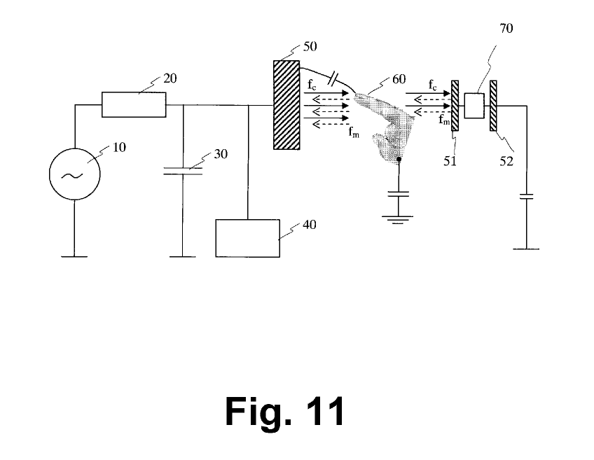

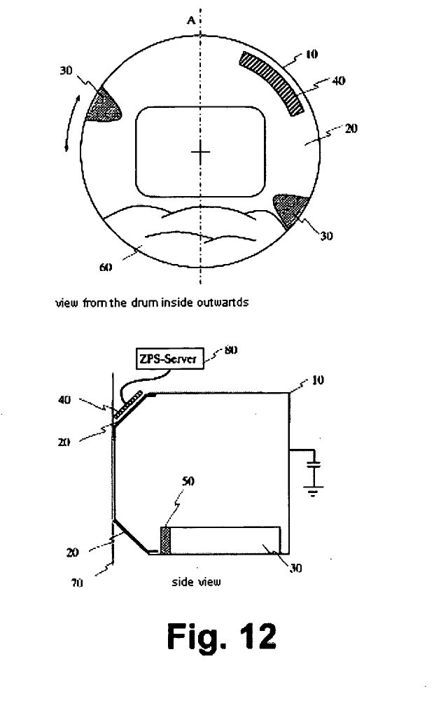

FIG. 11 shows another advantageous embodiment of the sensor device according to the invention. Here, too, the server circuit is constructed as shown in FIG. 1. The client circuit substantially also corresponds to the client circuit of FIG. 2, with the difference that the electrode 52 is capacitively coupled to earth. The client circuit is arranged with respect to the server circuit in such a way that the electric field radiated on the electrode 50 is coupled only with the electrode 51 of the client circuit, when a conductive object, for example a hand, is situated between the electrode 50 and the electrode 51. The signal radiated on the electrode 50 is transmitted by the object situated between the client circuit and the server circuit from the electrode 50 onto the electrode 51 (i.e. the electric field is coupled with the electrode 51 by means of the bridging effect of the conductive object).

The transmission of the signal modulated by the client circuit or the modulation device 70 by the object arranged between the two electrodes takes place in the same way. Here, too, the signal generated by the client circuit is amplitude-modulated.

As already described in FIG. 10, also in accordance with the embodiment according to FIG. 11 an approach of an object to the server electrode 50 causes an absorption of a part of the electric field radiated by the server electrode 50. Here, too, the absorption leads to a change in the frequency of the oscillator signal. Therefore, also in this embodiment, in an appropriate arrangement of the client circuit with respect to the server circuit, for instance as shown in FIG. 11, the approach of an object to the server electrode 50 can be detected, even before the object causes a bridging effect for the coupling of the electric field of the server electrode 50 with the electrode 51.

Here, too, the evaluation device 40 is constructed in such a way that it can detect and evaluate both the approach of an object to the server electrode 50 (frequency change) and the coupling of the electric field with the electrode 51 (amplitude variation).

Therefore, the server circuit of the sensor device according to the invention is constructed in such a way that the server circuit alone (i.e. without interaction with a client circuit) can be used as an approaching sensor, but at the same time a sensor network together with one or more client circuits is feasible as well in which the client circuits are supplied with energy preferably with the electric field of the server electrode 50. For instance, the construction of a sensor network with a server circuit and several client circuits can be made in such a way that the evaluation device of the server circuit can distinguish the single client circuits.

FIG. 12 is a view from inside outwards (above) as well as a side view (below) of a washing drum of a clothes dryer. The drum 10 has in its inside one or more lifters 30, which are used to take the washing along during the drum rotation. An electrode 40 is arranged in the upper frontal area of the drum. It is situated on the plastic cover 20. By means of this plastic cover 20 the electrode 40 is isolated from the drum inside. At the same time the electrode 40—because of the construction of the clothes dryer—is electrically shielded from the external environment by means of the earthed front wall 70 of the clothes dryer.

The electrode 40, presents a certain capacitive coupling with the environment. The capacitive coupling with the environment can be amplified, for example, through additional electrode surfaces or through a larger electrode surface of the electrode 40. In the front view of the washing drum shown in FIG. 1 an illustrated embodiment of the electrode 40 can be seen.

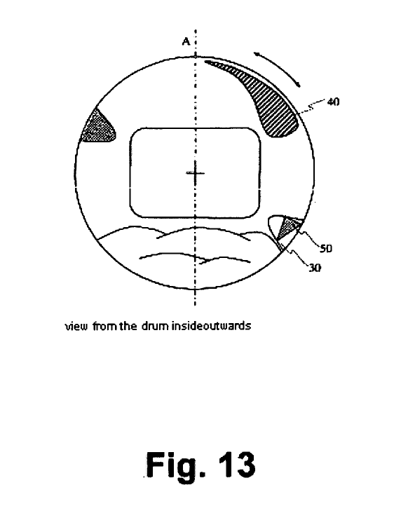

Other embodiments different from the ring segment shaped embodiment of the electrode shown here are possible. Particularly, an asymmetric embodiment, for instance an asymmetric embodiment with respect to the drum rotation direction, is also possible, which enables to determine the rotation direction even in case of an empty drum. Such an embodiment of an electrode is shown in FIG. 13. Here the electrode 40 is substantially wedge-shaped. In this case the signal generated during the drum rotation in interaction with the counter electrode (see below) depends on the drum rotation direction, so that the drum rotation direction can be deduced from the signal.

In the same way, the counter electrode 50 too can be asymmetric, particularly asymmetric with respect to the drum rotation direction. Here, too, the signal generated during the drum rotation in interaction with the counter electrode depends on the drum rotation direction.

In the embodiment shown here, the electrode 40 is constructed as a server electrode and is coupled with a server circuit (ZPS-Server 80).

The ZPS-Server 80 substantially presents a free-running LC oscillator for generating an electric field, which is radiated on the server electrode 40 coupled with the ZPS-server 80 preferably in the drum 10 inside. An emission of an electric field of the server electrode 40 is avoided in an area outside the clothes dryer because of the earthed front wall 70 or the earthed clothes dryer case. A serial LC oscillatory circuit with the server electrode 40 as (part of the) capacitance can be designed as a LC oscillator in the oscillatory circuit, so that the necessary increase in the electrode voltage on the server electrode 40 is reached as well.

Of course the server circuit can also consist of a simple circuit, for example a LC-circuit with an oscillator, for determining the capacitance change on the electrode. From the measured capacitance change it is then possible to determine the amount, the rotation direction or the degree of humidity on the basis of the arrangement of the server electrode and of the counter electrode according to the invention.

In an embodiment of the sensor device according to the invention the lifter 30 can be constructed as electrically conductive. In the embodiment shown in FIG. 12 only the side of the lifter 30 facing the server electrode 40 is constructed as electrically conductive. For instance, this can be achieved in that, on the side of the lifter facing the server electrode, should this part of the lifter 30 not be constructed as electrically conductive, an electrically conductive electrode, for example in the form of a conductive varnish or the like, is arranged.

Through the drum rotation 10 the lifters 30 pass by the server electrode 40. In this way the capacitive environment of the server electrode 40, which causes a change in the frequency of the oscillator or of the oscillatory circuit of the server circuit, changes. This frequency changes is used to detect the approach of the lifter 30 or of the electrodes 50 arranged on the lifter 30 to the server electrode 40.

The result of the evaluation of this frequency changes of the oscillator depends on the amount and on the degree of humidity of the washing situated in the drum 10.

During a rotation of the empty drum the lifters 30 or the electrodes 50 arranged on the lifter 30 pass by the server electrode 40. Thereby, the oscillator frequency of the server is modulated with the rotation frequency of the drum. Hence, for example, the rotational speed of the drum 10 can be ascertained.

Should the drum be loaded with wet washing (yet not fully loaded), the capacitive environment or rather the capacitance of the server electrode 40 varies not only through the lifters or through the electrode 50 arranged on the lifter 30, but also is through the washing carried by the server electrode 40. Here, too, the oscillator frequency is modulated with the rotation frequency of the drum. Hence, the rotational speed of the drum can be deduced again.

However, as the capacitance change or rather the change in the capacitive environment of the server electrode 40, in the case in which wet washing is carried by the server electrode 40, is greater than in case of an empty drum, the frequency change is accordingly greater as well. Therefore, from the frequency change the degree of humidity of the washing can be deduced as well. A frequency change, which is to be found in the range of a frequency change in case of an empty drum, implies that the washing in the drum is dry. This enables the drying process to take place with a certain dynamics and the frequency change to slowly approach the frequency change in case of an empty drum.

As shown in FIG. 12 in the view from inside outwards of the drum 10, the server electrode 40 is not arranged symmetrically to the axis A, but it is asymmetric to it. By this arrangement of the server electrode 40 according to the invention, the signal form of the frequency modulated oscillator frequency also depends on the drum 10 rotation direction. Thus, for example during a clockwise drum rotation a small quantity of washing taken along by the lifter falls down again before it reaches or passes the server electrode 40 and therefore generates a smaller signal than in the counterclockwise drum rotation, where the washing is almost completely carried by the server electrode 40.

As in case of a fully loaded drum no place or little place is available for the washing taken along by the lifters 30 to fall down again, the frequency modulated oscillator frequencies are very similar with respect to both rotation directions of the drum. From the similar signals for both rotation directions the evaluation unit can determine that the drum 10 is fully loaded with washing. Thereby, the amplitude of the frequency modulated oscillator frequency indicates the degree of humidity of the washing situated in the drum.

In this way a method can be provided for measuring the drum rotation direction, the amount and/or the degree of humidity of the washing in a washing machine or in a clothes dryer, which comprises at least the following steps:

1. The drum is rotated clockwise. Thereby relative changes in the signal (of the frequency modulated oscillator frequency) and/or the absolute change in the signal as opposed to the signal in case of a not loaded drum are detected.

2. Afterwards the drum is rotated counterclockwise. Here, too, relative changes in the signal and/or absolute changes in the signal as opposed to the signal in case of a not loaded drum are detected. Afterwards, the results of the second step are compared with the results of the first step.

Of course the order of the first two steps can be inverted, so that in a first step an counterclockwise drum rotation takes place and in the second step a clockwise drum rotation takes place.

3. In another step the required quantities, such as the amount of the washing situated in the drum or the degree of humidity of the washing, can be determined with one or more deposited formula(s) or transformation(s). The specific formulas and/or transformations to be used substantially depend on the specific embodiment of the drum 10. Thus, for instance, the dynamics of the frequency modulated oscillator frequency can depend on the arrangement or on the size of the lifters 30 arranged inside the drum. A lifter 30 protruding further into the drum inside implies that during a drum rotation much more washing is carried by the server electrode 40, which leads to a different frequency modulation of the oscillator frequency. Particularly, the dynamics of the frequency modulated oscillator signal can also depend on the drum 10 size or diameter, as in case of a bigger drum the washing taken along by the lifter 30 also during an counterclockwise rotation falls down again immediately before reaching the server electrode 40 so that, in order to determine the degree of humidity of the washing, other reference values must be employed than in case of a drum with a smaller diameter.

Moreover, this method can also present a calibration step in which the required reference values for determining the degree of humidity or the amount of washing in the drum are ascertained. This calibration step is preferably carried out with an empty drum, so that the frequency modulated oscillator signal can be detected both for a clockwise drum rotation and for an counterclockwise drum rotation. The frequency modulated oscillator signals generated or detected in this way, which are characteristic of an empty drum rotation, can be stored in a suitably provided storage, such as a non-volatile storage, in the server circuit or in the evaluation circuit. The stored signals (reference signals) can be then used in the steps 1) and 2) of the method as comparison signals for determining the absolute change in the current frequency modulated oscillator signals with respect to the signals of a not loaded drum.

If required, the calibration step can be repeated at any later moment, thus compensating for example environment-related or ageing-related influences on the sensor device at least with respect to the reference signals.

The arrangement of the sensor device according to the invention shown in FIG. 12 can also be used to detect the movement of a child or of an animal situated in the drum. Furthermore, a good focusing of the measurement in the changes in capacitance or in the capacitive environment of the server electrode is given by shielding the server electrode through the earthed appliance wall or through the earthed case only inside the drum.

By using a server circuit, additional electrodes or server electrodes can be connected to this server circuit, where the additional electrodes can be used for another purpose than determining the amount or the degree of humidity of the washing.

1. A safety device for detecting the presence of living beings inside an housing area of a household appliance, particularly a washing machine or a clothes dryer, with:
a first electrode device which, as such, is facing the housing area and is a component of a LC network, and
a second electrode device which is also facing the housing area and is a component of a LC network, and
an evaluation circuit for detecting electric field interactions with at least one of the two electrode devices.

2. The safety device according to claim 1 wherein by means of the evaluation circuit the dynamics of the electric field interactions is detected, and in that the detected dynamics is compared with the comparison values provided for the current working condition of the housing area, where, if the detected dynamics of differs from the provided comparison values, a safety function is activated.

3. The safety device according to claim 1 wherein the safety function consists in stopping a dangerous operation, or in that the safety function consists in an alarm issue.

4. The safety device according to claim 1 wherein the safety function consists in unlocking a door device.

5. The safety device according to claim 1 wherein the safety function requires an user's activation in order to continue the operation.

6. The safety device according to claim 1 wherein first of all a starting operation with reduced dynamics is promptly started.

7. The safety device according to claim 1 wherein by that starting operation the presence of dynamic characteristics is checked.

8. The safety device according to claim 1 wherein the first electrode device is operated as a transmitting electrode, in order to couple an electric field in a section of the housing area to be observed.

9. The safety device according to claim 1 wherein the second electrode device is made as a receiving electrode device.

10. The safety device according to claim 1 wherein the two electrode devices are operated in such a way that differences are detected in the electric fields adjacent to them.

11. The safety device according to claim 1 wherein generates the transmitting field is generated by electrode devices which are connected to a housing drum.

12. The safety device according to claim 1 wherein the receiving electrodes are connected to a detection circuit which, as such, generates signals which are caused through differences between the fields adjacent to the receiving electrodes, or through bridging effects between the two receiving electrodes.

13. The safety device according to claim 1 wherein a technical signal feedback of the events detected through the detecting circuit to a server circuit through the transmitting electrode system takes place.

14. A safety device for detecting the presence of living beings inside a housing drum constructed as a washing housing drum and lockable by means of a door of a washing machine or of a clothes dryer in which a first electrode device is connected to the washing housing drum and a second electrode device is connected to the door in which, on the basis of the electric field coupling of the electrode device on the drum side with the electrode device on the door side, it is determined if a living being is situated in the housing area.

15. The safety device according to claim 14 wherein the determination occurs by means of dynamic characteristics of the electric field coupling.

16. A sensor device for detecting an approach of an object in an observation area monitored by the sensor device, presenting a server circuit with a LC oscillatory circuit with a signal-generating circuit, preferably a high-quality LC oscillatory circuit, for generating an electric field;
an electrode device coupled with the LC oscillatory circuit in which the capacitance of the electrode device is a component of the oscillatory circuit capacitance and in which the electric field generated by the LC oscillatory circuit is radiated on the electrode device in the observation area; and
an evaluation device, wherein the approach of an object in the observation area of the electrode device causes a change in the capacitive environment of the electrode device, which is detectable by the evaluation device.

17. The sensor device according to claim 16 wherein the signal-generating circuit comprises an oscillator.

18. The sensor device according to claim 16 wherein the LC oscillatory circuit is a LC series resonant circuit and wherein the electrode device is connected in parallel to the LC series resonant circuit.

19. The sensor device according to claim 16 wherein the LC oscillatory circuit is a LC parallel resonant circuit and wherein the electrode device is connected in series to the LC parallel resonant circuit.

20. The sensor device according to claim 16 wherein the change in the capacitive environment of the electrode device causes a change in the frequency of the free-running LC oscillator in which the change in the frequency is detectable by the evaluation device.

21-44. (canceled)
